(19) United States
(12) Patent Application Publication
(10) Pub. No.: US 2012/0086453 A1
(43) Pub. Date: Apr. 12, 2012

(54) MRI WITH HYPERPOLARISATION DEVICE USING PHOTONS WITH ORBITAL ANGULAR MOMENTUM

(75) Inventors: Lucian Remus Albu, Forest Hills, NY (US); Daniel R. Elgort, New York, NY (US)

(73) Assignee: KONINKLIJKE PHILIPS ELECTRONICS N.V., EINDHOVEN (NL)

(21) Appl. No.: 13/378,193

(22) PCT Filed: Jun. 9, 2010
(86) PCT No.: PCT/IB10/52567

§ 371 Date: Dec. 14, 2011

Related U.S. Application Data
(60) Provisional application No. 61/218,464, filed on Jun. 19, 2009.

(51) Int. Cl. G01R 33/34

(52) U.S. Cl. 324/318

(57) ABSTRACT

A photonic-based hyperpolarisation device is disclosed with an electromagnetic source for emitting photonic radiation having a substantial penetration depth for material of the object, in particular of tissue, to be examined. For example, soft or ultra-soft x-rays are applied. Notably, the photonic-based hyperpolarisation device incorporates a magnet to generate a static magnetic field. Alternatively, the photonic-based hyperpolarisation device is incorporated in an magnetic resonance examination system.

### FIELD OF THE INVENTION

The invention pertains to a magnetic resonance examination system provided with a photonic based hyperpolarisation device.

### BACKGROUND OF THE INVENTION

Such a magnetic resonance examination system is described in the international application PCT/IB2008/055444.

The magnetic resonance examination system described in the above international application comprises a hyperpolarisation device that is optically based. In particular the hyperpolarisation device generates an optical (e.g. light) beam that is endowed with orbital angular momentum. The orbital angular momentum (OAM) of the light beam couples with (nuclear or molecular) dipoles (or spins) to generate (nuclear or molecular) polarisation. This polarisation is excited by RF-radiation and upon relaxation of the excitation, magnetic resonance signals are generated. From these magnetic resonance signals a magnetic resonance image is reconstructed. Because the polarisation is generated by the orbital angular momentum of the light beam, either no external magnetic field or only a weak magnetic field is needed to generate magnetic resonance signals with a relatively high signal-to-noise ratio. In the known optical-based hyperpolarisation device the probability of OAM interaction is higher when the beam diameter is smaller. the known magnetic resonance examination system requires an interventional procedure to generate polarisation in the interior of the object to be examined, notably a patient to be examined. In particular, a catheter or a needle probe is employed to hyperpolarise blood upstream from a region of interest.

### SUMMARY OF THE INVENTION

An object of the invention is to provide a magnetic resonance examination system with a photonic based that is more flexible to image the interior of the object to be examined.

This object is achieved by a magnetic resonance examination system of the invention comprising

an RF-system for inducing resonance in polarised dipoles and receiving magnetic resonance signals from an object to be examined

a photonic-based hyperpolarisation device with
an electromagnetic source for emitting photonic radiation having a substantial penetration depth for material of the object, in particular of tissue, to be examined
a mode converter to impart orbital angular momentum to the electromagnetic radiation
a spatial filter to select from the mode converter a diffracted or refracted photonic beam endowed with orbital angular momentum for polarising the dipoles via transferred orbital angular momentum.

Because the photonic radiation endowed with orbital angular momentum (OAM) penetrates the material, such as tissue of a patient to be examined, the photonic radiation endowed with OAM can reach the region of interest to be imaged from the outside of the object. Thus, hyperpolarisation of the material, such as tissue, is achieved within the object without the need of an interventional instrument, such as a catheter or a needle device. In particular photonic radiation having an energy in the ranges from 0.1 keV suitable to penetrate centimetres of skin, fat, metabolite fluids, brain tissue etc. or even up to 10 keV, suitable to penetrate centimetres of skull or bone tissues. The photonic radiation having energy in the x-ray range excites inner shell electron orbitals, notably this concerns the K,L and M shell electrons. Thus a large number of electrons interacts with the photonic radiation which causes enhancement of the photon-molecule interactions cross sections, therefore an enhancement of the OAM to molecular rotation transfer and electrons spin, which ultimately generate the magnetic hyperpolarized state required to obtain large signal to noise magnetic resonance signals.

Such magnetic resonance image can represent morphology of the object under examination, such as a patient to be examined. Also functional information may be represented, e.g. in the form or BOLD (blood oxygen level deficiency) signals. Alternatively, also magnetic resonance spectroscopy data can be reconstructed from the magnetic resonance signals.

These and other aspects of the invention will be further elaborated with reference to the embodiments defined in the dependent Claims.

In one example of the magnetic resonance examination system of the invention an optical system is provided to focus the photonic radiation endowed with OAM onto a target zone of particular interest. In this way the focal region is made narrow which enhances the degree of polarisation of material, such as tissue due to interaction of molecules or nuclei of the material to be examined. The enhanced degree of (hyper)polarisation improves the signal-to-noise ratio of the generated magnetic resonance signals.

In another example of the magnetic resonance examination system of the invention is provided with a set of polarisers to circularly polarise the photonic radiation from the electromagnetic source, a transmission phase hologram to impart the orbital angular momentum to circularly polarised photonic radiation and the focusing optics includes a parabolic cylindrical mirror with a convex mirror to focus the photonic radiation endowed with orbital angular momentum. The parabolic cylindrical mirror forms a number of parallel beams that are energy separated. Within the range of 0.1 keV to 10 keV focusing can be achieved by way of Fresnel plates, which are diffraction networks confining concentric metallic circles with the pitch at a minimum value of 40 nm, same as the diffraction gratings. Accordingly, a desired energy can be selected by a beam stop that is positioned to block the parallel beams that have an energy outside of the desired range. Good results are achieved in particular when the ratio of the pitch of the hologram grating pattern to the wavelength of the x-rays is in the range of 4:1 at 0.1 keV or 400:1 at 10 keV. for a 40 nm grid pitch at 0.1 keV (10 nm wavelength) the ratio is 4:1. The same grating used at 10 keV (0.1 nm) produces the expected OAM beam, this time the grid pitch to wavelength is at 400:1. For both cases, the diffraction grating angle (˜5.00 and respectively ˜0.050) allow the separation of the first diffraction order from the 0th diffraction order after a short optical path of 25 cm. the K,L, and M orbital absorption transitions are quasi continuous for X-rays in the 0.1 to 10 keV range, therefore the induced molecular torque transitions has a long lifetime (large cross section) proportional to the OAM value.

In a further aspect of the invention concave moveable mirrors are provided to scan the photonic beam endowed with angular momentum of a field of view. In this way the focal spot of the beam is scanned and at successive positions in the field of view hyperpolarisation en ensuingly magnetic resonance signals are generated. This allows to dispense with a magnetic gradient field for spatial encoding of the magnetic resonance signals. Hence, in a further aspect of the invention the magnetic resonance signals is provided with a magnet system to only provide a static magnetic field.

These and other aspects of the invention will be elucidated with reference to the embodiments described hereinafter and with reference to the accompanying drawing wherein

### BRIEF DESCRIPTION OF THE DRAWINGS

FIG. 1 shows a diagrammatic representation of an embodiment of the photonic hyperpolarisation device that is employed in conjunction with a magnetic resonance examination system in accordance with the invention,

FIG. 2 shows a diagrammatic representation of an magnetic resonance examination system of the invention that operates in conjunction with the photonic hyperpolarisation device of FIG. 1.

### BRIEF DESCRIPTION OF THE DRAWINGS

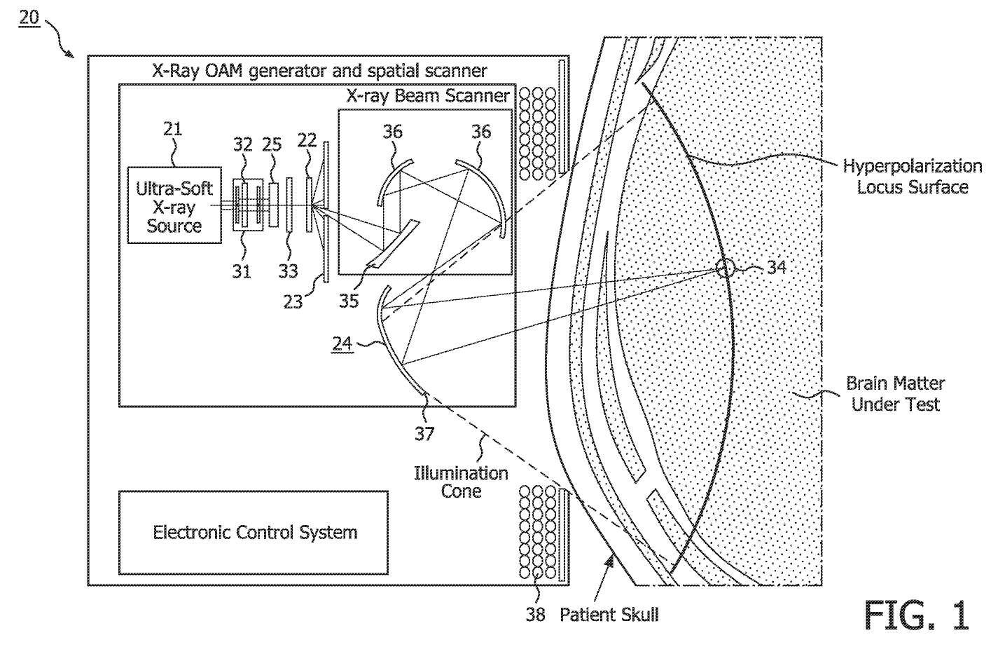

FIG. 1 shows a diagrammatic representation of an embodiment of the photonic hyperpolarisation device which includes an (miniature) x-ray source 21 as the electromagnetic source. Miniature broad band x-ray sources have energies in the range from 0.1 keV to 10 keV, i.e. ultra-soft or soft x-rays. The material of the anode of an X-ray source manifests as a narrow energy peak, placed within the [0.1 keV-40 keV] range (mentioned above) at energies specific to the anode type (e.g. 1.8 keV for Al, 2 keV for Si, 8 keV for Cu Kα, 9 keV for Cu Kβ). For some applications, these peaks are used for increasing the power conversion efficiency of the X-ray tube. The x-ray source includes an energy filter 31 includes an energy filter which filters e.g. for the Lα shell energy levels. A beam collimator 32 collimates the filtered x-ray beam. The collimated beam is polarised and circularly polarised by a set of polarisers and quarter waveplate 33. Then the circularly polarised x-ray beam is passed through the transmissive phase hologram 22 that endows the x-ray photons with orbital angular momentum (OAM). Then the first diffraction order is selected by the spatial filter 23; this spatial filter selects the photons that are endowed with OAM. The parabolic cylindrical mirror 35 creates a parallel beam of x-rays endowed with OAM. This allows to perform energy separation of the x-rays. A set of movable concave mirrors 36 together with a parabolic mirror 37 form the focusing optics 24 which focuses the x-ray beam endowed with OAM onto a geometric locus on a hemisphere. In the example shown, the focus lies within a human brain. The centre of the domain of analysis is at the equivalent conjugate focal point of the parabolic mirror, consequently the Field Of View (FOV) is a spherical calotte with a radius of curvature of up to 5 cm and a maximum angle of view of ˜90° (a function of the focal value of the concave mirrors).

The focusing optics with the moveable concave mirrors produce a focal point at any point on the surface of this FOV. At the focal point, the OAM of the X-ray photons is transferred to molecules. As mentioned before, this will re-direct the molecular angular momentum towards the direction of the incident beam. Along with the electron spin orbital population saturation, this effect contributes to the nuclear orientation towards the incident beam of light (hyperfine coupling), hence at the focal point we will obtain a hyperpolarized state of matter. The polarization degree obtained through this technique is orders of magnitude better than what is possible to obtain through the Zeeman effect.

The large magnetic polarization degree allows the usage of a very low B₀ magnetic field for nuclear magnetic resonance. To that end coils 38 are provided which generate the low magnetic field. At the same time, no extra RF shielding is required, since the NMR signal is very strong and the focal point where the NMR is observed is close to the receiving RF coil. The magnetic field created by the coil 38 (B0 and RF coils) in not necessarily uniform. The non-uniformity of B0 needs to be addressed by a “factory calibration of the device”, which also referred to a ‘shimming’, where a B0 spatial distribution and X-ray focal points spatial mapping needs to be performed and correlated accordingly, such that for any focal point(s) of the X-ray beam, the amplitude and orientation of the magnetic field is known, and the broad band receiving coil is properly adjusted (tuned) to capture the MRS signals in their frequency band. Because the coils which generate the static magnetic field are incorporated in the photonic hyperpolarisation device, there is no need for a fixedly mounted main magnet so that the magnetic resonance examination system of the invention can be designed as a portable system.

Unlike in a conventional MRI, there is no need for a gradient coil; instead, the spatial encoding is performed through the sequential movement of the focal point, which can sample the matter with a fundamental spatial resolution of the size of the focal point of ˜10 nm³. Practically, the device resolution will be limited by target molecule concentrations, the scanning capabilities of the focusing optics and acquisition time. Every RF measurement sequence acquires the wide band FID obtained through focusing the signal at one focal point in space (on the focal point surface locus) and pulsing the X-ray source (FID sequences trigger). B0 non-uniformity effects are to be compensated for by pre-calibration techniques.

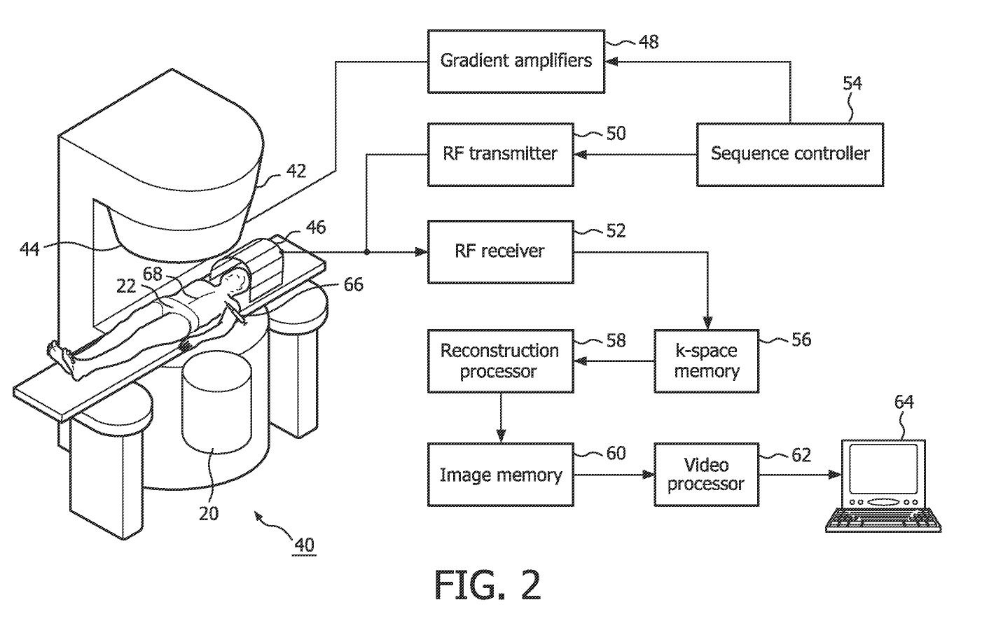

In another embodiment, as shown in FIG. 2, the photonic based hyperpolarisation device 20 as described above can be used in conjunction with a magnetic resonance scanner 40. For example, the photonic based hyperpolarisation device 20 is incorporated in the structure of the magnetic resonance scanner, more in particular the photonic based hyperpolarisation device 20 can be employed as a separate module. The magnetic resonance scanner 40 can be an open field system (open MRI system) that includes a vertical main magnet assembly 42. The main magnet assembly 42 produces a substantially constant main magnetic field oriented along a vertical axis of an imaging region. Although a vertical main magnet assembly 42 is illustrated, it is to be understood that other magnet arrangements, such as cylindrical, and other configurations are also contemplated. In this embodiment the coils 38 of the photonic hyperpolarisation device 20 can be dispensed with. Alternatively, the static magnetic field of the coils 38 of the photonic based hyperpolarisation device generate a static magnetic field that is parallel to the static magnetic field of the magnetic resonance scanner.

A gradient coil assembly 44 produces magnetic field gradients in the imaging region for spatially encoding the main magnetic field. Preferably, the magnetic field gradient coil assembly 44 includes coil segments configured to produce magnetic field gradient pulses in three orthogonal directions, typically longitudinal or z, transverse or x, and vertical or y directions. Both the main magnet assembly 42 and the gradient field assembly 44 in some embodiments are used along with optical polarization.

A radio frequency coil assembly 46 (illustrated as a head coil, although surface and whole body coils are also contemplated) generates radio frequency pulses for exciting resonance in dipoles of the subject. The radio frequency coil assembly 46 also serves to detect resonance signals emanating from the imaging region. The radio frequency coil assembly 46 can be used to supplement optical perturbation of previously established polarization.

Gradient pulse amplifiers 48 deliver controlled electrical currents to the magnetic field gradient assembly 44 to produce selected magnetic field gradients. A radio frequency transmitter 50, preferably digital, applies radio frequency pulses or pulse packets to the radio frequency coil assembly 46 to excite selected resonance. A radio frequency receiver 52 is coupled to the coil assembly 46 or separate receive coils to receive and demodulate the induced resonance signals.

To acquire resonance imaging data of a subject, the subject is placed inside the imaging region. A sequence controller 54 communicates with the gradient amplifiers 48 and the radio frequency transmitter 50 to supplement the optical manipulation of the region of interest. The sequence controller 54 may, for example, produce selected repeated echo steady-state, or other resonance sequences, spatially encode such resonances, selectively manipulate or spoil resonances, or otherwise generate selected magnetic resonance signals characteristic of the subject. The generated resonance signals are detected by the RF coil assembly 46, communicated to the radio frequency receiver 52, demodulated and stored in a k-space memory 56. The imaging data is reconstructed by a reconstruction processor 58 to produce one or more image representations that are stored in an image memory 60. In one suitable embodiment, the reconstruction processor 58 performs an inverse Fourier transform reconstruction.

The resultant image representation(s) is processed by a video processor 62 and displayed on a user interface 64 equipped with a human readable display. The interface 64 is preferably a personal computer or workstation. Rather than producing a video image, the image representation can be processed by a printer driver and printed, transmitted over a computer network or the Internet, or the like.

Preferably, the user interface 64 also allows a radiologist or other operator to communicate with the sequence controller 54 to select magnetic resonance imaging sequences, modify imaging sequences, execute imaging sequences, and so forth.

1. An magnetic resonance examination system comprising
an RF-system for inducing resonance in polarised dipoles and receiving magnetic resonance signals from an object to be examined
a photonic-based hyperpolarisation device with
an electromagnetic source for emitting photonic radiation having a substantial penetration depth for material of the object, in particular of tissue, to be examined
a mode converter to impart orbital angular momentum to the electromagnetic radiation
a spatial filter to select from the mode converter a diffracted or refracted photonic beam endowed with orbital angular momentum for polarising the dipoles via transferred orbital angular momentum.

2. A magnetic resonance examination system as claimed in claim 1, wherein the photonic-based hyperpolarisation device includes focusing optics to focus the photonic beam endowed in orbital angular momentum.

3. A magnetic resonance examination system as claimed in claim 2, wherein the hyperpolarisation device includes
a set of polarisers to circularly polarise the photonic radiation from the electromagnetic source
a transmission phase hologram to impart the orbital angular momentum to circularly polarised photonic radiation and
the focusing optics includes a parabolic cylindrical mirror with a convex mirror to focus the photonic radiation endowed with orbital angular momentum.

4. A magnetic resonance examination system as claimed in claim 3, wherein a set of moveable concave mirrors is located in the exiting beam path from the parabolic cylindrical mirror.

5. A magnetic resonance examination system as claimed in claim 1, wherein a magnet system is provided to generate a static spatially uniform magnetic field in an examination zone, without spatial gradient magnetic fields.

6. A magnetic resonance examination system as claimed in claim 1, wherein a magnet to generate a static magnetic field in an examination zone is incorporated in the photonic-based hyperpolarisation device and the photonic-based hyperpolarisation device is configured to direct the photonic beam endowed with orbital angular momentum into the examination zone.
